(19) United States
(12) Patent Application Publication
(10) Pub. No.: US 2016/0035698 A1
(43) Pub. Date: Feb. 4, 2016

(54) STACK PACKAGE

(71) Applicant: SAMSUNG ELECTRONICS CO., LTD., Suwon-Si (KR)

(72) Inventors: CHEOL-WOO LEE, ANYANG-SI (KR); WAN-HO PARK, ASAN-SI (KR)

(21) Appl. No.: 14/719,411

(22) Filed: May 22, 2015

(30) Foreign Application Priority Data
Jul. 29, 2014 (KR) 10-2014-0096770

(51) Int. Cl. H01L 25/065; H01L 23/00; H01L 25/18

(52) U.S. Cl. CPC H01L 25/0652; H01L 25/18; H01L 24/33; H01L 2924/1434; H01L 2924/1431

(57) ABSTRACT

A stack package includes a substrate, a stack of semiconductor chips mounted to the substrate, a side semiconductor chip disposed on one side of the stack, and adhesive interposed between the lower surface of the side semiconductor chip and the stack of semiconductor chips and which attaches the side semiconductor chip to the stack.

### PRIORITY STATEMENT

This application claims the benefit of Korean Patent Application No. 10-2014-0096770, filed on Jul. 29, 2014, in the Korean Intellectual Property Office, the disclosure of which is hereby incorporated by reference in its entirety.

### BACKGROUND

The inventive concept relates to semiconductor device packages. More particularly, the inventive concept relates to a semiconductor device package having a stack of semiconductor chips.

### SUMMARY

According to an aspect of the inventive concept, there is provided a semiconductor device stack type of package including a substrate, a stack of semiconductor chips disposed on and mounted to the substrate such that the stack has a bottom at which the stack sits on the substrate, a top, and a side region extending between the bottom and the top of the stack, at least one side semiconductor chip attached to the stack of semiconductor chips at the side region of the stack of semiconductor chips, and an adhesive member interposed between a lower surface of the at least one side semiconductor chip and the side region of the stack of semiconductor chips and by which the side semiconductor chip is attached to the stack of semiconductor chips.

According to another aspect of the inventive concept, there is provided a semiconductor device stack type of package that includes a substrate including an insulating body and connection pads disposed along at least one of the sides of the insulating body, a stack of semiconductor chips disposed stepwise on the substrate and having a plurality of stack-chip connection pads exposed at a side of the stack, at least one side semiconductor chip that has a plurality of side-chip connection pads at an upper surface thereof, and an adhesive member attached to the stack at the side thereof where the stack-chip connection pads are exposed and by which the side semiconductor chip is attached to the stack.

According to another aspect of the inventive concept, there is provided a semiconductor device stack type of package including

an electronic substrate including a board and electrical connections including conductive pads disposed on one of the major surfaces of the board, a stack of first semiconductor chips mounted to the substrate on said one of the major surfaces with each of the first semiconductor chips being electrically connected to the electrical connections of the substrate, a second semiconductor chip including a chip body and conductive pads disposed along one surface of the chip body, and electrical connectors electrically connecting the second semiconductor chip to the electronic substrate, and in which the second semiconductor chip is attached to the stack of semiconductor chips at one of the side regions of the stack with the one surface of the chip body facing away from the side region and the other surface of the chip body facing towards the side regions, and the electrical connectors electrically connect the conductive pads of the second semiconductor chip to respective ones of the conductive pads of the electronic substrate.

### BRIEF DESCRIPTION OF THE DRAWINGS

Exemplary embodiments of the inventive concept will be more clearly understood from the following detailed description taken in conjunction with the accompanying drawings in which:

FIG. 1A is a schematic plan view showing a layout of a stack package according to an exemplary embodiment;

FIG. 1B is a cross-sectional view taken along line B1-B1′ in FIG. 1A;

FIG. 1C is an exploded view of region A in FIG. 1B;

FIG. 2 is a schematic plan view showing a layout of a stack package according to another exemplary embodiment;

FIG. 3 is a schematic plan view showing a layout of a stack package according to another exemplary embodiment;

FIG. 4 is a cross-sectional view of a stack package according to another exemplary embodiment, taken along the line B1-B1′ in FIG. 1A;

FIG. 5A is a schematic plan view showing a layout of a stack package according to another exemplary embodiment;

FIG. 5B is a cross-sectional view taken along line B5-B5′ in FIG. 5A;

FIGS. 6A, 6B, 6C and 6D are cross-sectional views that sequentially show a manufacturing method of a stack package according to an exemplary embodiment;

FIGS. 7A, 7B, 7C, 7D and 7E are cross-sectional views that sequentially show a manufacturing method of a stack package according to another exemplary embodiment;

FIG. 8 is a schematic block diagram of a memory card including a stack package according to exemplary embodiments;

FIG. 9 is a schematic block diagram of an electric system including a stack package according to exemplary embodiments;

FIG. 10 is a schematic plan view of a solid state drive (SSD) employing a stack package according to exemplary embodiments of the present inventive concept; and

FIG. 11 is a schematic perspective view of an electronic apparatus employing a stack package according to exemplary embodiments.

### DETAILED DESCRIPTION OF THE PREFERRED EMBODIMENTS

The inventive concept will now be described more fully with reference to the accompanying drawings, in which exemplary embodiments of the inventive concept are shown. Like reference numerals denote like elements, and thus detailed descriptions thereof will not be repeated.

The inventive concept may, however, be embodied in many different forms and should not be construed as being limited to the example embodiments set forth herein; rather, these embodiments are provided so that this disclosure will be thorough and complete, and will fully convey the inventive concept to those of ordinary skill in the art.

It will be understood that, although the terms “first” “second” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Unless otherwise defined, all terms (including technical and scientific terms) used herein have the same meaning as commonly understood by one of ordinary skill in the art to which exemplary embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Variations from the shapes of the illustrations as a result, for example, of manufacturing techniques and/or tolerances, are to be expected. Thus, exemplary embodiments should not be construed as limited to the particular shapes of regions illustrated herein but are to include deviations in shapes that result, for example, from manufacturing.

As used herein, the term “and/or” includes any and all combinations of one or more of the associated listed items. Expressions such as “at least one of”, when preceding a list of elements, modify the entire list of elements and do not modify the individual elements of the list.

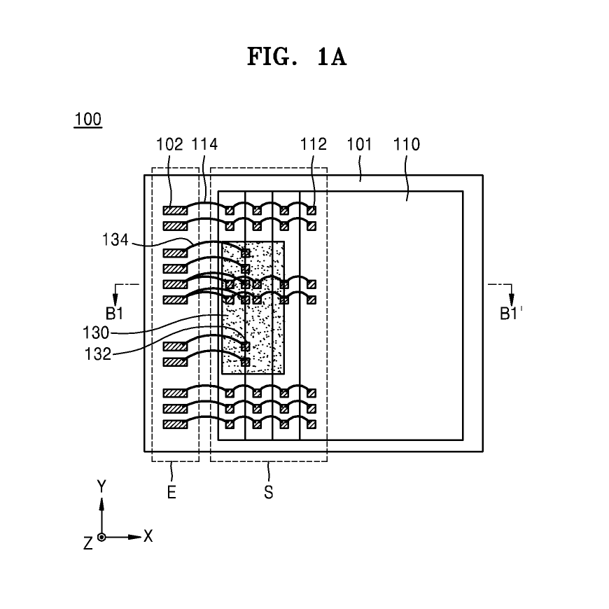

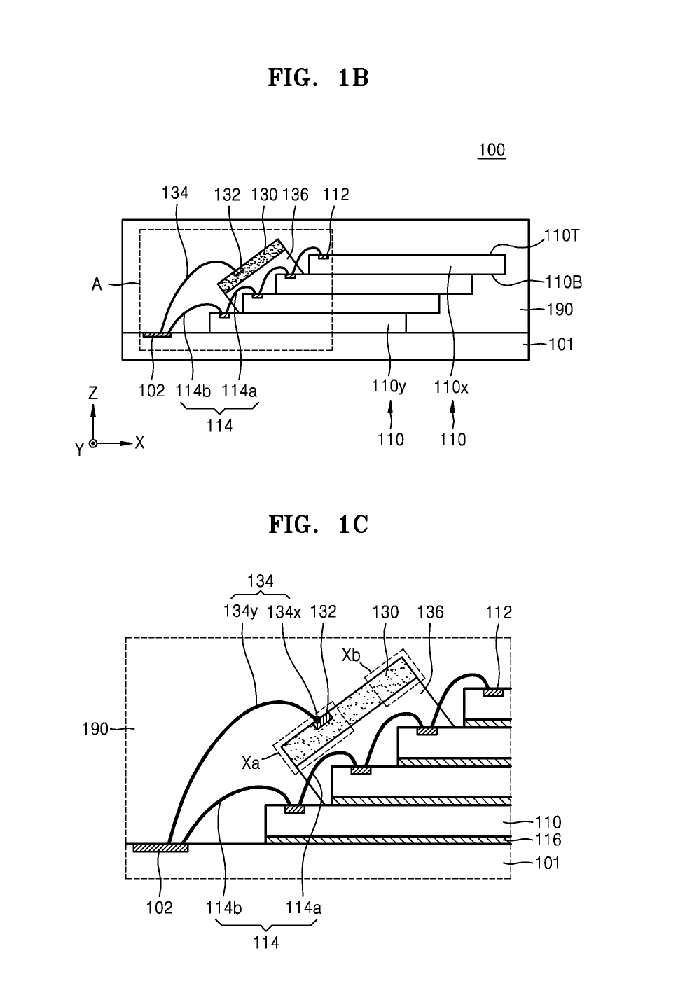

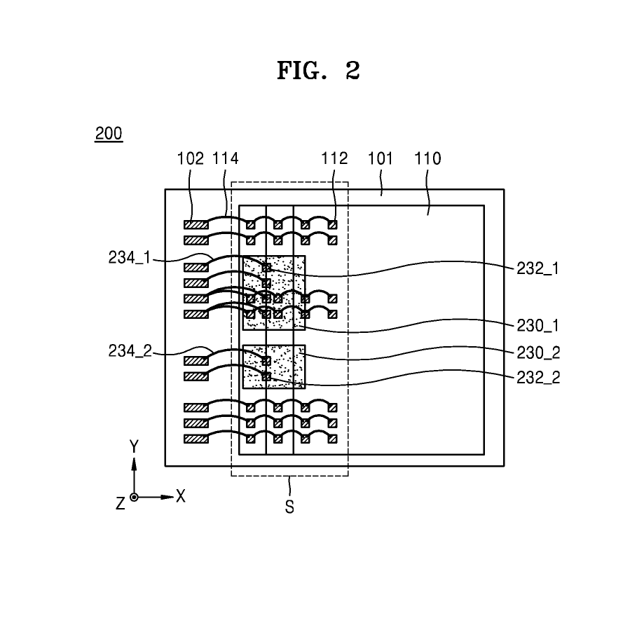

An embodiment of stack package according to the inventive concept will now be described in more detail with reference to FIGS. 1A to 1C.

Stack package 100 includes a substrate 101, stack semiconductor chips 110 stacked on the substrate 101, a side semiconductor chip 130 mounted on the stack semiconductor chips 110 and a mold portion 190 covering the stack semiconductor chips 110 and the side semiconductor chip 130.

The stack semiconductor chips 110 and the side semiconductor chip 130 are mounted on the substrate 101, and the substrate 101 may be a printed circuit board (PCB), i.e., an insulating body in the form of a board having conductive patterns one or both sides thereof. The PCB may be a single-sided PCB, a double-sided PCB, or a multi-layered PCB including one or more internal wiring patterns. In addition, the PCB may be a rigid-PCB or a flexible-PCB.

In an example of this embodiment, the substrate 101 is a multi-layered PCB having a body of insulating layers, a wiring pattern (not shown) inside the body of the substrate 101, and a plurality of connection pads 102 disposed on an upper surface of the body of the substrate 101 and electrically connected to the wiring pattern.

Although not shown in the drawings, the substrate 101 may further include a plurality of lower connection pads (not shown) that are disposed on the lower surface of the body of substrate 101 and electrically connected to the wiring pattern, and an external connecting member (not shown) disposed on the lower connection pads facilitates the mounting of the stack package 100 on an external system substrate or a main board.

Each of the connection pads 102 on the substrate 101 is formed of a conductive material and may electrically connect the substrate 101 and semiconductor chips 110 and 130 via connecting members 114 and 134. The connection pads 102 may be formed of aluminum (Al), copper (Cu), or the like, and may be formed by pulse plating or direct current plating.

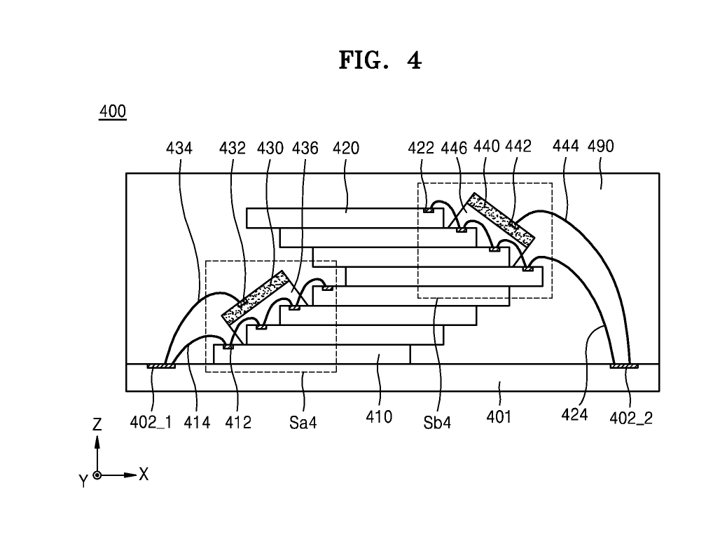

As shown in FIG. 1A, the connection pads 102 are spaced from one another, along one side edge region E, in a second direction (Y-axis direction in FIG. 1A) of the substrate 101 which is perpendicular to a first direction (X-axis direction in FIG. 1A). However, the disposition of the connection pads 102 is not limited thereto. The connection pads may be disposed in spaced apart sets along two edge regions Ea and Eb, respectively, as shown in FIG. 3.

Each of the stack semiconductor chips 110 has a chip body having one surface 110T on which a plurality of stack-chip connection pads 112 are disposed, and another surface 110B that is on an opposite side of the chip with respect to the one surface 110T.

The stack semiconductor chips 110 may comprise an IC configured to provide a memory device or a logic device, and to which the stack-chip connection pads are electrically connected. Examples of a memory device include a dynamic random access memory (DRAM), a static random access memory (SRAM), a flash memory, an electrically erasable programmable read-only memory (EEPROM), a phase-change random access memory (PRAM), a magnetic random access memory (MRAM), and a resistive random access memory (RRAM).

The stack-chip connection pads 112 are disposed on one side S of the one surface 110T of each of the stack semiconductor chips 110. More specifically, the stack-chip connection pads 112 may be spaced from one another in the second direction (Y-axis direction) on at least one side S of the one surface 110T of each of the stack semiconductor chips 110. The stack semiconductor chips 110 are stacked stepwise in the first direction (X-axis direction) on the upper surface of the substrate 101 to expose each of the stack-chip connection pads 112.

An adhesive member 116 is formed on the other surface 110B of each of the stack semiconductor chips 110. The adhesive member 116 may be one of a non-conductive film (NCF), an anisotropic conductive film (ACF), a UV film, an instant adhesive, a thermosetting adhesive, a laser-setting adhesive, an ultrasonic-setting adhesive and a non-conductive paste (NCP).

The stack semiconductor chips 110 are stacked in a face-up type of disposition in which the one surface 110T of each of the stack semiconductor chips 110 faces up in a third direction (Z-axis direction in FIG. 1B), which is normal to a plane in which the first direction (X-axis direction) and the second direction (Y-axis direction) lie, but the stacked type is not limited thereto. For example, the stack semiconductor chips 110 may be stacked in a face-down type of disposition in which the one surface 110T of each of the stack semiconductor chips 110 faces down in the third direction (Z-axis direction). In this case, each of the stack semiconductor chips 110 may have a through silicon via (TSV) (not shown) by which the chips 110 are electrically connected to one another.

As mentioned above, the stack semiconductor chips 110 are electrically connected to the substrate 101 via a first connecting member 114. For example, the stack semiconductor chips 110 are electrically connected to one another via a first connecting member 114a, and at least one stack semiconductor chip of the stack semiconductor chips 110 may be electrically connected to the substrate 101 via a first connecting member 114b.

In some exemplary embodiments, the first connecting member 114 is a bonding wire. The bonding wire may be formed of gold, silver, copper, aluminum, or an alloy thereof. Alternatively, the first connecting member 114 may be a solder ball, a flip-chip bonding member, a bump, a conductive via such as a though silicon via (TSV) or a combination of such connecting members.

The side semiconductor chip 130 is attached on one side S of the stack of semiconductor chips 110 by an adhesive member 136. By attaching the side semiconductor chip 130 on the one side S, the side semiconductor chip 130 may be inclined with respect to the substrate 101 or the stack semiconductor chips 110. The (footprint of the) side semiconductor chip 130 may be smaller than (the footprint of) each of the stack semiconductor chips 110.

The side semiconductor chip 130, like the stack semiconductor chips 110, comprises an IC, and has a chip body and connection pads electrically connected to the IC.

In some exemplary embodiments, the chip body of the side semiconductor chip 130 has a first edge region Xa where the connection pads 132 (referred to hereinafter as “side-chip connection pads”) are disposed, and a second edge region Xb opposite to the first edge region Xa, and the first edge region Xa of the side semiconductor chip 130 may be lower than the second edge region Xb in the package.

In some exemplary embodiments, the side semiconductor chip 130 and the adhesive member 136 may be spaced along the side S from at least one of the uppermost stack semiconductor chip 110x and the lowest stack semiconductor chip 110y. More specifically, a projection of the footprint of the side semiconductor chip 130 normal to its orientation may strike some or all of the stack semiconductor chips 110 except for the uppermost stack semiconductor chip 110x and/or the lowest stack semiconductor chip 110y. That is, for example, the side semiconductor chip 130 may overlap at least one of the middle stack semiconductor chips 110 in a plan view of the package, as is shown in FIG. 1A.

The side semiconductor chip 130 may comprise an IC configured to provide a memory device or a logic device. In one example of this embodiment, both the stack semiconductor chips 110 and the side semiconductor chip 130 are all memory devices or logic devices. Alternatively, the stack semiconductor chips 110 may be memory devices and the side semiconductor chip 130 may be a logic device, or vice versa. For example, the stack semiconductor chips 110 are memory devices and the side semiconductor chip 130 is a logic device.

The adhesive member 136 fixes the side semiconductor chip 130 on the side S of the stack semiconductor chips 110. The adhesive member 136 may be formed of a (cured) liquid adhesive or may be an adhesive film. For example, the adhesive member 136 may be at least one of a NCF, an ACF, a UV film, an instant adhesive, a thermosetting adhesive, a laser-setting adhesive, an ultrasonic-setting adhesive and an NCP similar to the adhesive member 116.

In some exemplary embodiments, the adhesive member 136 may have a film over wire (FOW) property.

FOW property refers to a viscosity that does not have an interference effect on the stack semiconductor chips 110 disposed on the substrate 101 and the first connecting member 114. In other words, FOW property is a property similar to that of a gel. Here, the adhesive member 136 has the property of a gel before hardening. In this gel-like state, the adhesive member 136 has an adhesiveness by which the side chip 130 is attached to the side S of the stack of chips 110, and a gel-like property which allows the first connecting member 114 to be embedded in the adhesive member 136. The first connecting member 114 embedded in the adhesive member 136 experiences no interference effect, such as a short, due to the viscosity of the adhesive member 136.

As was also mentioned above, the side semiconductor chip 130 is electrically connected to the substrate 101 via a second connecting member 134. More specifically, the second connecting member 134 connects the side-chip connection pads 132 at the upper surface of the side semiconductor chip 130 and at least some of the connection pads 102 at the upper surface of the substrate 101.

In some exemplary embodiments, the second connecting member 134 may comprise a bonding wire. In a case in which the second connecting member 134 comprises a bonding wire, the second connecting member 134 may consist of a bonding bump 134x on each connection pad 132 and a respective bonding wire 134y bonded by the bump 134x to the pad 132, as shown in FIG. 1C. The bonding bump 134x may be formed before the side semiconductor chip 130 is attached to the side S of the stack semiconductor chips 110, or after the side semiconductor chip 130 is attached to the one side S. Alternatively, a bonding bump similar to bonding bump 134x may be formed on each upper connection pad 102 of the substrate 101 instead of on the associated connection pad 132 of the side semiconductor chip 130. In still another example, a respective bonding bump 134x may be formed both on the stack-chip connection pad 132 and each upper connection pad 102 connected thereto.

In some exemplary embodiments, although not shown in the drawings, the second connecting member 134 may comprise a conductive thin film or the like formed by a tape automated bonding (TAB) method.

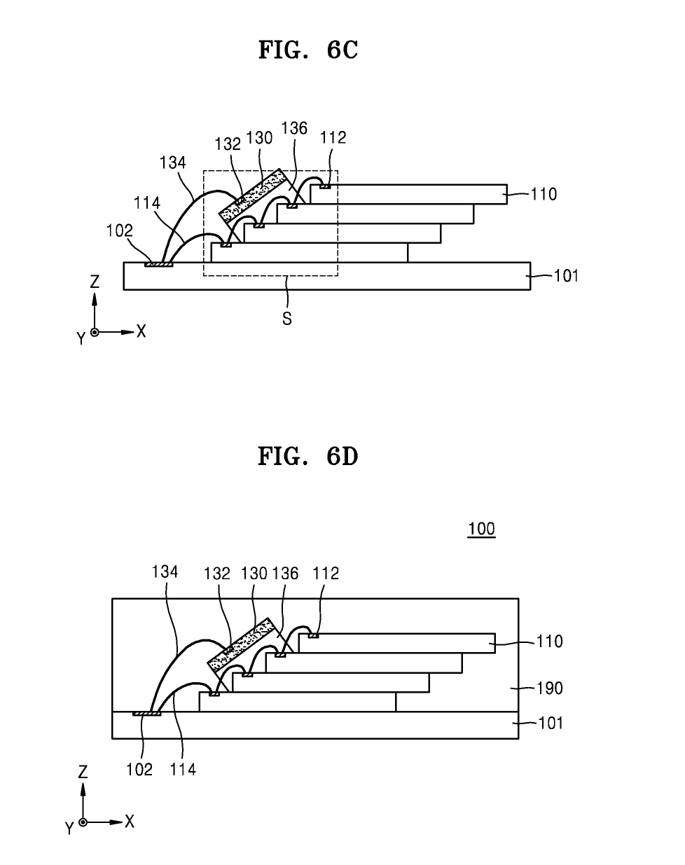

The mold portion 190 is formed to cover the semiconductor chips 110 and 130 and connecting members 114 and 134 on the substrate 101 and to protect the semiconductor chips 110 and 130 and the connecting members 114 and 134 from external impacts. The mold portion 190 may comprise an epoxy-group molding resin, a polyimide-group molding resin, or the like, and further details of the mold portion 190 will be described below with reference to FIG. 6D.

In the stack package 100 according to the current exemplary embodiment, the side semiconductor chip 130 is disposed on one side S of the stack semiconductor chips 110. Thus, the second connecting member 134 may be relatively short, whereby signals can be efficiently transmitted of between the substrate 101 and the side semiconductor chip 130. In this case, the cross-sectional area of the stack package 100 may be smaller compared to a package in which a semiconductor chip is directly disposed on a substrate as spaced laterally from a stack semiconductor chips. The height of the stack package 100 may be less than that of a corresponding package in which all of the chips are stacked one atop the other.

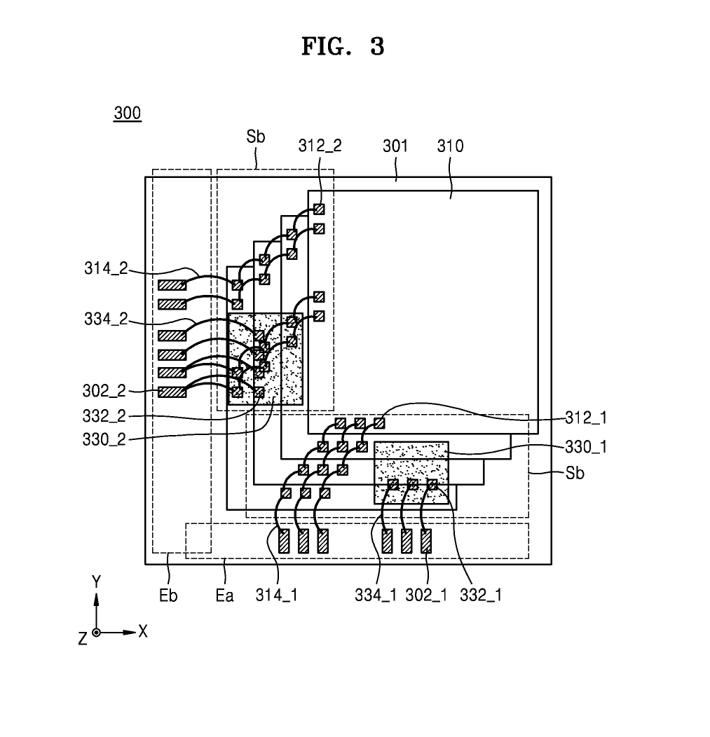

FIG. 2 shows another exemplary embodiment of a stack package according to the inventive concept.

Stack package 200 includes a substrate 101, semiconductor chips 110 stacked on the substrate 101 and side semiconductor chips 230_1 and 230_2 attached to the stack semiconductor chips 110.

Two side semiconductor chips 230_1 and 230_2 are illustrated, but the number of the side semiconductor chips is not limited thereto.

The side semiconductor chips 230_1 and 230_2 may be attached to one side S of the stack semiconductor chips 110. Although not illustrated in drawings, each of the side semiconductor chips 230_1 and 230_2 may be attached to the one side S via an independent connecting member (not shown). The side semiconductor chips 230_1 and 230_2 may be inclined with respect to the substrate 101 or the stack semiconductor chips 110 in a similar manner to the side semiconductor chip 130 as shown in FIG. 1B. Each of the side semiconductor chips 230_1 and 230_2 may be smaller than each of the stack semiconductor chips 110.

The side semiconductor chips 230_1 and 230_2 according to the current exemplary embodiment are aligned in the second direction (Y-axis direction), but one of the side semiconductor chips 230_1 and 230_2 may be offset in the first direction (X-axis direction) relative to the other.

The side semiconductor chips 230_1 and 230_2 may be memory devices or logic devices. The side semiconductor chip 230_1 and the side semiconductor chip 230_2 may be different or identical types of semiconductor chips.

The side semiconductor chips 230_1 and 230_2 are electrically connected to the substrate 101 via the second connecting members 234_1 and 234_2. More specifically, a second connecting member 234_1 connects a plurality of side-chip connection pads 232_1 formed on the upper surface of the side semiconductor chip 230_1 and at least one of a plurality of connection pads 102 formed on the upper surface of the substrate 101 while a second connecting member 234_2 connects a plurality of side-chip connection pads 232_2 formed on the upper surface of the side semiconductor chip 230_2 and at least one of a plurality of connection pads 102 formed on the upper surface of the substrate 101

The second connecting members 234_1 and 234_2 may be a bonding wire. The second connecting members 234_1 and 234_2 may be, like the first connecting member 114, any one of various types of connecting members that can electrically connect the substrate 101 and the side semiconductor chips 230_1 and 230_2. The second connecting member 234_1 and the second connecting member 234_2 may be of the same type.

FIG. 3 shows another exemplary embodiment of a stack package according to the inventive concept.

Stack package 300 includes a substrate 301, stack semiconductor chips 310 stacked on the substrate 301 and side semiconductor chips 330_1 and 330_2 attached to the stack semiconductor chips 310.

The substrate 301 may be a PCB like the substrate 101 described with reference to FIGS. 1A and 1B. The substrate 301 according to the current exemplary embodiment includes a plurality of connection pads 302_1 spaced from one another on a first edge region Ea extending in the first direction (X-axis direction), and a plurality of connection pads 302_2 spaced from one another on a second edge region Eb extending in the second direction (Y-axis direction).

The connection pads 302_1 and 302_2 may be formed of a conductive material at the upper surface of the substrate 301 to electrically connect the substrate 101 and the semiconductor chips 310, 330_1 and 330_2 via connecting members 314_1, 314_2, 334_1, and 334_2. The connection pads 302_1 and 302_2 may be formed of aluminum, copper, or the like, and may be formed by pulse plating or direct current plating.

The stack semiconductor chips 310 may be memory devices or logic devices, like the stack semiconductor chips 110 described with reference to FIGS. 1A and 1B

Each of the stack semiconductor chips 310 includes a plurality of stack-chip connection pads 312_1 spaced from each other along a first edge region Sa in the first direction (X direction) and a plurality of side-chip connection pads 312_2 spaced from each other along a second edge region Sb in the second direction (Y direction). Each of the stack semiconductor chips 310 is stacked stepwise on the upper surface of the substrate 301 to expose the stack-chip connection pads 312_1 and 312_2.

The stack semiconductor chips 310 are electrically connected to the substrate 301 via the first connecting members 314_1 and 314_2. More specifically, the first connecting member 314_1 sequentially connects the stack-chip connection pads 312_1 formed on the upper surface of the stack semiconductor chips 310 and at least one of the connection pads 302_1 formed on the upper surface of the substrate 101 while the first connecting member 314_2 sequentially connects the stack-chip connection pads 312_2 formed on the upper surface of the stack semiconductor chips 310 and at least one of the connection pads 302_2 formed on the upper surface of the substrate 101.

The first connecting members 314_1 and 314_2 may be bonding wires or various other types of connecting members, like those mentioned regarding the first connecting member 114 of the embodiment of FIGS. 1A and 1B which can electrically connect the substrate 301 and the stack semiconductor chips 310. The first connecting member 314_1 and the first connecting member 314_2 may be of the same type.

The side semiconductor chips 330_1 and 330_2 may be attached to the first edge region Sa and the second edge region Sb of the stack semiconductor chips 310, respectively, so as to be spaced from each other. Alternatively, the side semiconductor chips 330_1 and 330_2 may be both attached to one of the first edge region Sa and the second edge region Sb like the embodiment of FIG. 2. In addition, one of the side semiconductor chips 330_1 and 330_2 may be attached to an edge region, and the other side semiconductor chip may be attached to the upper surface of the substrate 301 or to the upper surface of the uppermost one of the stack semiconductor chips 310.

Although two of the side semiconductor chips 330_1 and 330_2 are illustrated the number of side semiconductor chips is not limited thereto.

The side semiconductor chips 330_1 and 330_2 may be inclined with respect to the substrate 301 or the stack semiconductor chips 310 in a similar manner to the side semiconductor chip 130 of FIG. 1B. Each of the side semiconductor chips 330_1 and 330_2 may be smaller than each of the stack semiconductor chips 310.

The side semiconductor chips 330_1 and 330_2 may be memory devices or logic devices. The side semiconductor chip 330_1 and side semiconductor chip 330_2 may be different types of chips or may be identical types of chips.

The side semiconductor chips 330_1 and 330_2 are electrically connected to the substrate 301 via the second connecting members 334_1 and 334_2. More specifically, the second connecting member 334_1 connects a plurality of side-chip connection pads 332_1 formed at the upper surface of the side semiconductor chip 330_1 and at least one of a plurality of connection pads 302_1 formed at the upper surface of the substrate 301 while the second connecting member 334_2 connects a plurality of side-chip connection pads 332_2 formed at the upper surface of the side semiconductor chip 330_2 and at least one of a plurality of connection pads 302_2 formed at the upper surface of the substrate 301.

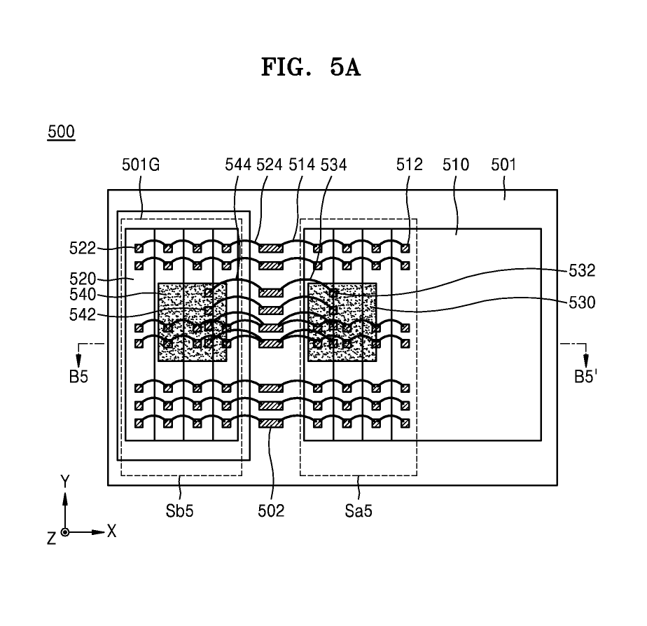

FIG. 4 shows another exemplary embodiment of a stack package according to the inventive concept.

Stack package 400 includes a substrate 401, first and second stack semiconductor chips 410 and 420 stacked on the substrate 401 and first and second side semiconductor chips 430 and 440 respectively attached to the first and the second stack semiconductor chips 410 and 420.

The substrate 401 may be a PCB like the substrate 101 described with reference to FIGS. 1A and 1B. The substrate 401 has connection pads 402_1 spaced from each other in the second direction (Y-axis direction) along one side edge region and a plurality of connection pads 402_2 spaced from each other in the second direction (Y-axis direction) along the other side edge region opposite the one side edge region.

The connection pads 402_1 and 402_2 are formed of a conductive material at the upper surface of the substrate 401 to electrically connect the substrate 401 and the semiconductor chips 410, 420, 430, and 440 via connecting members 414, 424, 434, and 444.

The first stack semiconductor chips 410 and the second stack semiconductor chips 420 may be memory devices or logic devices similar to the first stack semiconductor chips 110 described with reference to FIGS. 1A and 1B. The first stack semiconductor chips 410 and the second stack semiconductor chips 420 may be identical types of semiconductor chips.

Each of the first stack semiconductor chips 410 includes a plurality of first stack-chip connection pads 412 spaced from one another in the second direction (Y direction) along one side Sa4 while each of the second stack semiconductor chips 420 includes a plurality of second stack-chip connection pads 422 spaced from one another in the second direction (Y direction) along the other side Sb4 which is opposite the one side Sa4.

The first stack semiconductor chips 410 are stacked stepwise on the upper surface of the substrate 401 in the first direction (X direction in FIG. 4) to expose each of the first stack-chip connection pads 412 while the second stack semiconductor chips 420 are stacked stepwise on the uppermost one of the first stack semiconductor chips 410 in an opposite direction to the first direction (−X direction in FIG. 4) to expose each of the second stack-chip connection pads 422.

The first stack semiconductor chips 410 and the second stack semiconductor chips 420 are electrically connected to the substrate 401 via the connecting members 414 and 424. More specifically, the first connecting member 414 sequentially connects the first stack-chip connection pads 412 formed at the upper surface of the first stack semiconductor chips 410 and at least one of the connection pads 402_1 formed at the upper surface of the substrate 401 while the second connecting member 424 sequentially connects the second stack-chip connection pads 422 formed at the upper surface of the second stack semiconductor chips 420 and at least one of the connection pads 402_2 formed at the upper surface of the substrate 401.

Each of the first side semiconductor chip 430 and the second side semiconductor chip 440 may be respectively attached to one side Sa4 and the other side Sb4 via adhesive members 436 and 446 while being inclined thereto.

In the current exemplary embodiment, the first side semiconductor chip 430 is attached to one side Sa4 while the second side semiconductor chip 440 is attached to the other side Sb4, but they are not limited thereto. For example, the first side semiconductor chip 430 and the second side semiconductor chip 440 may be attached to one of the sides Sa4 and Sb4. Also, one of the first side semiconductor chip 430 and the second side semiconductor chip 440 may be attached to an edge region, and the other of them may be attached to the upper surface of the substrate 401. In another example of this embodiment, one of the first side semiconductor chip 430 and the second side semiconductor chip 440 is omitted.

The first side semiconductor chip 430 and the second side semiconductor chip 440 may be memory devices or logic devices. The first side semiconductor chip 430 and the second side semiconductor chip 440 may be different or identical types of semiconductor chips.

The first side semiconductor chip 430 and the second side semiconductor chip 440 are electrically connected to the substrate 401 via the connecting members 434 and 444. More specifically, a third connecting member 434 connects a plurality of first side-chip connection pads 432 formed at the upper surface of the first side semiconductor chip 430 and at least one of the connection pads 402_1 formed at the upper surface of the substrate 401 while a fourth connecting member 444 connects a plurality of second side-chip connection pads 442 formed at the upper surface of the second side semiconductor chip 440 and at least one of the connection pads 402_2 formed at the upper surface of the substrate 401

In the stack package 400 according to the current exemplary embodiment, the first and the second stack semiconductor chips 410 and 420 are stacked stepwise and the first and the second side semiconductor chips 430 and 440 are disposed on edge regions Sa4 and Sb4, thereby providing a stack package with a high density and high performance.

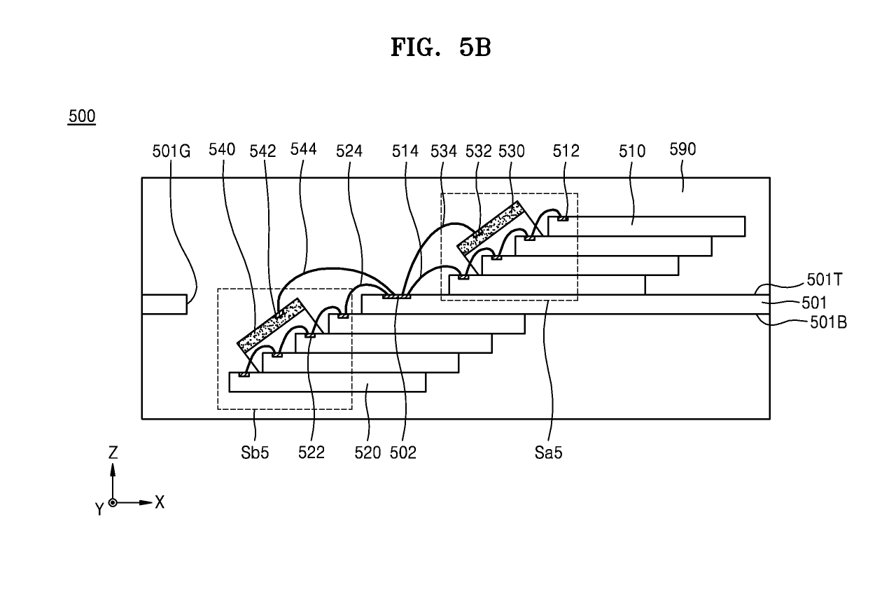

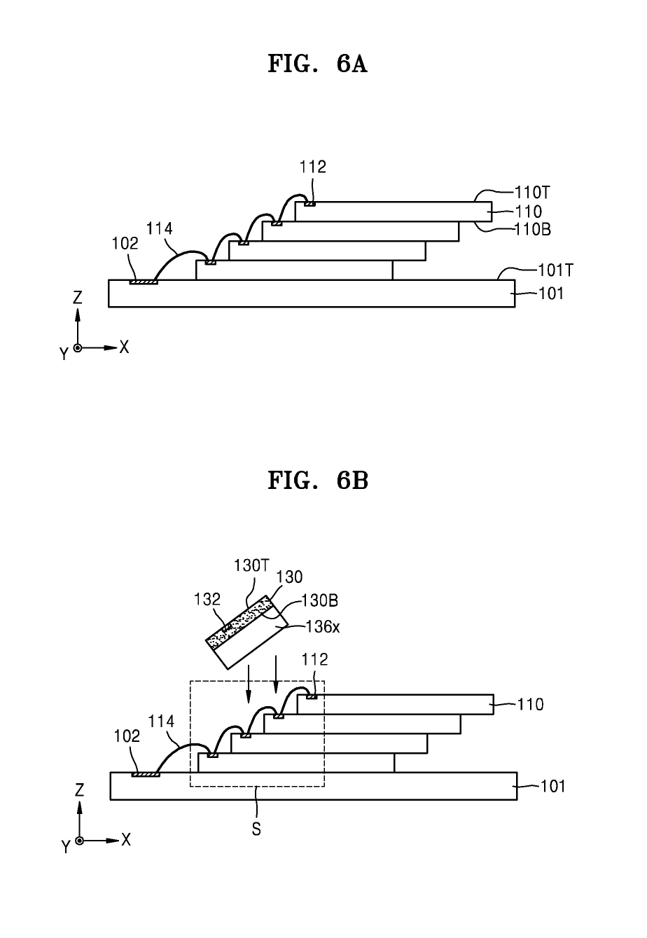

FIG. 5A show another exemplary embodiment of a stack package according to the inventive concept.

Stack package 500 includes a substrate 501, first and second stack semiconductor chips 510 and 520 stacked on the substrate 501, and first and second side semiconductor chips 530 and 540 respectively attached to the first and the second stack semiconductor chips 510 and 520.

The substrate 501 includes an insulating body in the form of a board having opposite major surfaces 501T and 501B, a plurality of connection pads 502 formed at the one surface 501T, and an opening 501G that passes through the insulating body from the one surface 501T to the other surface 501B. The substrate 501 may be a PCB like the substrate 101 of FIGS. 1A and 1B.

A plurality of connection pads 502 are spaced from one another in the second direction (Y-axis direction) along the one surface 501T of the substrate 501, adjacent to opening 501G.

The connection pads 502 are made of a conductive material and electrically connect the substrate 501 and the semiconductor chips 510, 520, 530 and 540 via the connecting members 514, 524, 534 and 544.

The opening 501G provides a path along which the second stack semiconductor chips 520 and the second side semiconductor chip 540 stacked on the other surface 501B of the substrate 501 are electrically connected to the substrate 501. In other words, the second connecting member 524 may pass through the opening 501G to electrically connect the second stack semiconductor chips 520 and the substrate 501, and the fourth connecting member 544 may also pass through the opening 501G to electrically connect the second side semiconductor chip 540 and the substrate 501.

The opening 501G may also be provided in a region in which a wiring pattern was not formed on the surface of or within the substrate 501.

In any case, the size of the opening 501G may be based on the size of each of the second stack semiconductor chips 520 and the second side semiconductor chip 540 that are stacked on the surface 501B of the substrate 501, the locations of the connection pads 522 and 542, etc. Accordingly, the size of the opening 501G, as shown in FIGS. 5A and 5 B, may be large enough to expose all of the connection pads 522 and 542 disposed on the surface 501B of the substrate 501, or may be smaller than the aforementioned example to expose some of the connection pads 522 and 542.

The connection pads 502 are formed between the first stack semiconductor chips 510 on the one surface 501T of the substrate 501 and the opening 501G, and electrically connect the substrate 501 and the semiconductor chips 510, 520, 530, and 540 via connecting members 514, 524, 534, and 544.

The first stack semiconductor chips 510 and the second stack semiconductor chips 520 may be memory devices or logic devices similarly to the first stack semiconductor chips 110 described with reference to FIGS. 1A and 1B. The first stack semiconductor chips 510 and the second stack semiconductor chips 520 may be the identical types of semiconductor chips.

The first stack semiconductor chips 510 include first stack-chip connection pads 512 spaced from one another in the second direction (Y direction) along one side Sa5 of each of the first stack semiconductor chips 510 while the second stack semiconductor chips 520 include second stack-chip connection pads 522 spaced from one another in the second direction (Y direction) along one side Sb5 of each of the second stack semiconductor chips 520.

The first stack semiconductor chips 510 are stacked stepwise on the one surface 501T of the substrate 501 to expose each of the first stack-chip connection pads 512 while the second stack semiconductor chips 520 are stacked stepwise on the other surface 501B of the substrate 501 to expose each of the second stack-chip connection pads 522.

Although not illustrated in drawings, an adhesive member (not shown) such as an adhesive film may be interposed between each of the first and the second stack semiconductor chips 510 and 520 and the substrate 501.

The first connecting member 514 sequentially connects the first stack-chip connection pads 512 formed at the upper surface of the first stack semiconductor chips 510 and at least one of the connection pads 502 formed at the upper surface of the substrate 501 while the second connecting member 524 sequentially connects the second stack-chip connection pads 522 formed at the upper surface of the second stack semiconductor chips 520 and at least one of the connection pads 502 formed at the upper surface of the substrate 501 through the opening 501G.

Each of the first side semiconductor chip 530 and the second side semiconductor chip 540 may be respectively attached to the one side Sa5 of the first stack semiconductor chips 510 and to one side Sb5 of the second stack semiconductor chips 520 via the adhesive members 436 and 446, while being inclined thereto.

In the current exemplary embodiment, the first side semiconductor chip 530 is attached to the one side Sa5 of the first stack semiconductor chips 510 while the second side semiconductor chip 540 is attached to the one side Sb5 of the second stack semiconductor chips 520, but they are not limited thereto. Alternatively, both the first side semiconductor chip 530 and the second side semiconductor chip 540 may be disposed on either the side edge region (Sa5) of the first stack semiconductor chips 510 or the side edge region(Sb5) of the second stack semiconductor chips 520. Also, the first side semiconductor chip 530 or the second side semiconductor chip 540 may be attached to an edge region, and the other semiconductor chip may be attached to the upper surface of the substrate 501. In another example of the current exemplary embodiment, one of the first side semiconductor chip 530 and the second side semiconductor chip 540 is omitted.

The first side semiconductor chip 530 and the second side semiconductor chip 540 may be memory devices or logic devices. The first side semiconductor chip 530 and the second side semiconductor chip 540 may be different or identical types of semiconductor chips.

The first side semiconductor chip 530 and the second side semiconductor chip 540 are electrically connected to the substrate 501 via the connecting members 534 and 544. The third connecting member 534 connects a plurality of first side-chip connection pads 532 formed on the upper surface of the first side semiconductor chip 530 and at least one of the connection pads 502 formed at the upper surface of the substrate 501 while the fourth connecting member 544 connects a plurality of second side-chip connection pads 542 formed at the upper surface of the second side semiconductor chip 540 and at least one of the connection pads 502 formed at the upper surface of the substrate 501 through the opening 501G.

In the stack package 500 according to the current exemplary embodiment, the first and the second stack semiconductor chips 510 and 520 are stacked stepwise with respect to the substrate 501, and the first and the second side semiconductor chips 530 and 540 are disposed on the edge regions Sa5 and Sb5 thereby providing a stack package with a high density and high performance.

FIGS. 6A to 6D show an exemplary embodiment of a method of manufacturing a stack package according to the inventive concept.

Referring to FIG. 6A, a substrate 101 having connection pads 102 at one surface 101T thereof, and a stack of semiconductor chips 110 mounted to the surface 110T, are provided. Each of the chips 110 has connection pads 112 at an upper surface 110T thereof. Although not illustrated in the drawings, an adhesive member (not shown) may be formed on the other surface 110B of each of the semiconductor chips 110 and used to adhere one of the chips 110 to the substrate 101, and the remainder of the chips to each other such that the chips 110 are stacked one atop the other on the substrate 101. The adhesive member may be one of an adhesive film such as a non conductive film (NCF), an anisotropic conductive film (ACF), and an UV film, a liquid adhesive such as an instant adhesive, a thermosetting adhesive, a laser-setting adhesive, or an ultrasonic-setting adhesive and an NCP. The adhesive member may be formed by spin coating, painting, spraying or the like.

In this respect, the semiconductor chips 110 are stacked stepwise on the substrate 101 to expose the stack-chip connection pads 112.

A hardening process may further be performed to harden the adhesive member formed on the other surface 110B of each of the stack semiconductor chips 110. The hardening process may be a heat treatment process, a thermo-compression process, a UV treatment process, or the like, selected depending on the composition of the adhesive member.

Also, the first connecting member 114 is provided. In a case in which the first connecting member 114 is a bonding wire, for example, the first connecting member 114 may be formed by using a forward folded loop mode method or a reverse loop mode method. In the case in which a forward folded loop mode method is used, one end of a bonding wire would first be ball-bonded to a stack-chip connection pad 112, and then the other end of the first connecting member 114 would be stitch-bonded to a stack-chip connection pad 112 or connection pad 102. On the other hand, in the case in which a reverse loop mode method is used, one end of the bonding wire would first be ball-bonded to a stack-chip connection pad 112 or connection pad 102, and the other end of the first connecting member 114 would then be stitch-bonded to a stud bump (not shown) formed on a stack-chip connection pad 112.

Referring to FIG. 6B, a side semiconductor chip 130 having a plurality of side-chip connection pads 132 formed at one surface 130T and an adhesive layer 136x formed on the other surface 130B is provided.

A process of fabricating the side semiconductor chip 130 may include, for example, preparing a wafer (not shown) on one surface of which the side-chip connection pads 132 are formed, forming the adhesive layer 136x on the other surface of the wafer, and separating the wafer into a plurality of side semiconductor chips 130 by a slicing process such as sawing the wafer with a blade.

In some exemplary embodiments, a stud bump (not shown) may further be formed on each of the side-chip connection pads 132 of the side semiconductor chip 130 for the wire bonding process according to the reverse loop mode method described above.

The adhesive layer 136x may be an NCF, an ACF, an UV film, an NCP, or the like, and the adhesive layer 136x may have a FOW property (refer back to the description of such an adhesive made with reference to FIGS. 1A to 1C).

Referring to FIG. 6C, the side semiconductor chip 130 is attached to one side S of the stack of semiconductor chips 110, and the second connecting member 134 is provided to electrically connect the substrate 101 and the side semiconductor chip 130.

A process of attaching the semiconductor chip 130 to the side S of the stack of semiconductor chips 110 may include picking the side semiconductor chip 130 at the surface 130T thereof with the head of a tool (not shown) such as the suction head of a vacuum device, tilting or otherwise rotating the head of the tool over a predetermined angle to tilt the side semiconductor chip 130 with respect to the stack semiconductor chips 110, and in this state pressing the adhesive layer 136x (see FIG. 6B) against the side S of the stack of semiconductor chips 110.

During the aforementioned process, at least some portions of the first connecting member 112 may be embedded in the adhesive member 136 due to the FOW property of the adhesive member 136.

After attaching the side semiconductor chip 130 to the side S of the stack of semiconductor chips 110, a hardening (i.e., curing process) may be performed to harden the adhesive member 136. The hardening process may be a heat treatment process, a thermo-compression process, a UV treatment process, or the like, selected depending on the composition of the adhesive member 136.

The second connecting member 114 may be attached to the connection pads in a manner similar to that of the first connecting member 114 aforementioned.

Referring to FIG. 6D, the mold portion 190 is fabricated to cover the semiconductor chips 110 and 130 and the connecting members 114 and 134 on the substrate 101.

The mold portion 190 may be formed by depositing an appropriate amount of molding resin onto the substrate 101 using an element (for example, a nozzle) of a dispenser and pressing the molding resin into shape using a device (not shown) such as a press.

Process conditions such as the time between the processes of dispensing of the molding resin and the molding of the resin deposited on the substrate, the amount of molding resin dispensed onto the substrate, the temperature in which the molding process takes place, and the pressure may be set in consideration of the physical characteristics, such as the viscosity, of the molding resin.

In some exemplary embodiments, the molding resin may be an epoxy-group molding resin or polyimide-group molding resin. Examples of the epoxy-group molding resin include a polycyclic aromatic epoxy resin, bisphenol-group epoxy resin, naphthalene-group epoxy resin, ortho-cresol novolac epoxy resin, dicyclopentadiene epoxy resin, biphenyl-group epoxy resin, and phenol novolac epoxy resin.

In some exemplary embodiments, the molding resin may include carbon black that is a colorant.

Also, the molding resin may further include a hardener, a hardening accelerator, a filler, and a flame retardant.

The hardener may be amine, polycyclic aromatic phenol resin, phenol novolac resin, cresol novolac resin, dicyclopentadiene phenol resin, xyloc resin, or naphthalene resin

Examples of a hardening accelerator that may be used as a catalyst for accelerating the hardening reaction between the epoxy-group molding resin and the hardener include tertiary amines such as benzyldimethylamine, triethanolamine, triethylenediamine, dimethylaminoethanol, and tris(dimethylaminomethyl)phenol, imidazols such as 2-methylimidazol and 2-phenylimidazol, organic phosphines such as triphenylphosphine, diphenylphosphine, and phenylphosphine, and tetraphenyl boron salts such as tetraphenylphosphonium, tetraphenylborate, and triphenylphosphine.

An example of the filler that may be used is silica and examples of the flame retardant include a brominated epoxy resin, antimony oxide, and metallic hydride.

The molding resin may further include a mold release agent such as a high quality fatty acid, high quality fatty acid metal salt, or ester-based wax and a tension relaxant such as modified silicone oil, silicon powder, or silicon resin.

The molding resin may be selected in consideration of its ability to mold well under certain conditions due to its viscosity. In this respect, the molding resin may be selected from among those having the physical characteristics of a fluidic solid such as a gel.

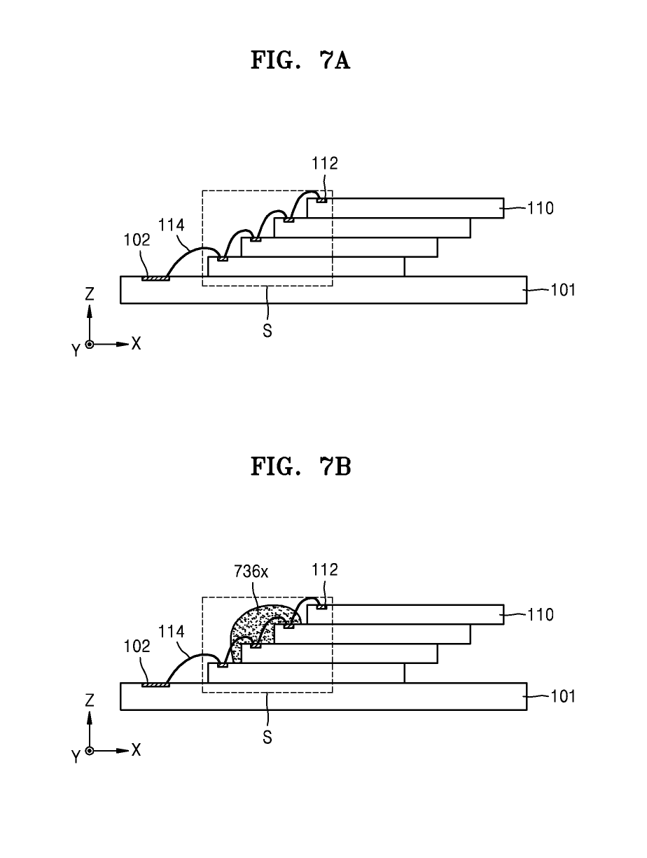

FIGS. 7A to 7E show another exemplary embodiment of a method of manufacturing a stack package 700 (FIG. 7E) according to the inventive concept.

Referring to FIG. 7A, the stack semiconductor chips 110 are stacked stepwise on the substrate 101 to expose the stack-chip connection pads 112 as described with reference to FIG. 6A, and then the first connecting member 114 is provided.

Referring to FIG. 7B, one side S of the stack semiconductor chips 110 is coated with an adhesive 736x.

The adhesive 736x may be an epoxy resin such as an o-cresol novolac epoxy resin, a bisphenol-group epoxy resin, or a rubber-modified epoxy resin, or an acrylate compound such as trimethylolpropane triacrylate, tetramethylol methane tetraacrylate, pentaerythritol triacrylate, or epoxy acrylate.

In some exemplary embodiments, the adhesive 736x may include a low-molecular weight compound so that the first connecting member 114 may be embedded inside the adhesive 736x. For example, the adhesive 736x may include an epoxy resin, whose weight per equivalent epoxy (WPE) is in a range of about 100 to about 1000, such as a cresol novolac epoxy resin, a solid bisphenol A-type epoxy resin, a liquid bisphenol A-type epoxy resin, a bisphenol F-type epoxy resin, or a rubber-modified epoxy resin.

In some exemplary embodiments, adhesive 736x may further include a hardener, a hardening accelerator, or the like.

Examples of a suitable hardener include amine, polycyclic aromatic phenol resin, phenol novolac resin, cresol novolac resin, dicyclopentadiene phenol resin, xyloc resin, and naphthalene resin

Examples of the hardening accelerator suitable as a catalyst for accelerating a hardening reaction between the epoxy-group molding resin and the hardener include tertiary amines such as benzyldimethylamine, triethanolamine, triethylenediamine, dimethylaminoethanol, and tris(dimethylaminomethyl)phenol, imidazols such as 2-methylimidazol and 2-phenylimidazol, organic phosphines such as triphenylphosphine, diphenylphosphine, and phenylphosphine, and tetraphenyl boron salts such as tetraphenylphosphonium, tetraphenylborate, and triphenylphosphine.

Referring to FIG. 7C, the side semiconductor chip 130 that has the side-chip connection pads 132 at one surface 130T thereof is provided. The side semiconductor chip 130 may be prepared in a manner similar to that described with reference to 6B.

Referring to FIG. 7D, the side semiconductor chip 130 is pressed onto adhesive 736x formed on the side S of the stack semiconductor chips 110. Then the second connecting member 134 is connected to connection pads 102, 132 to electrically connect the substrate 101 and the side semiconductor chip 130.

After pressing the side semiconductor chip 130 onto the adhesive 736x, a hardening process may further be performed to cure the adhesive 763x and thereby form the adhesive member 736. The hardening process may be a heat treatment process, a thermo-compression process, a UV treatment process, or the like, selected considering the composition of the adhesive 736x.

Referring to FIG. 7E, the mold portion 190 that covers the semiconductor chips 110 and 130 and connecting members 114 and 134 on the substrate 101 is formed.

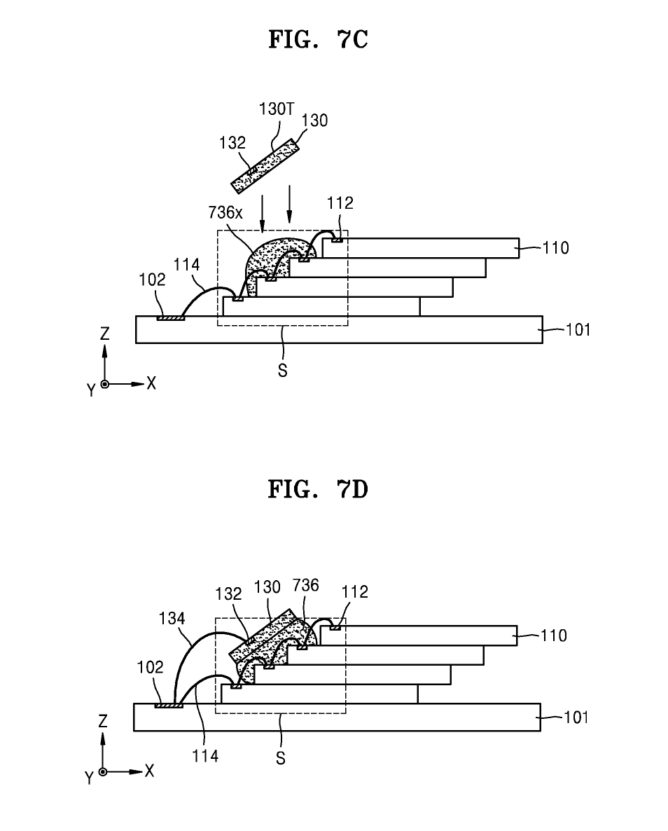

FIG. 8 is a schematic block diagram of a memory card including a stack package according to exemplary embodiments.

Referring to FIG. 8, a controller 11 and a memory 12 may be operatively connected to exchange electrical signals in a memory card 10. For example, if the controller 11 sends a command, the memory 12 may transmit data. The controller 11 and/or the memory 12 may include a stack package according to an exemplary embodiment. The memory 12 may include a memory array (not shown) or a memory array bank (not shown).

The memory card 10 may be a memory stick card, a smart media (SM) card, a secure digital (SD) card, a mini secure digital (mini SD) card, or a multi media card (MMC).

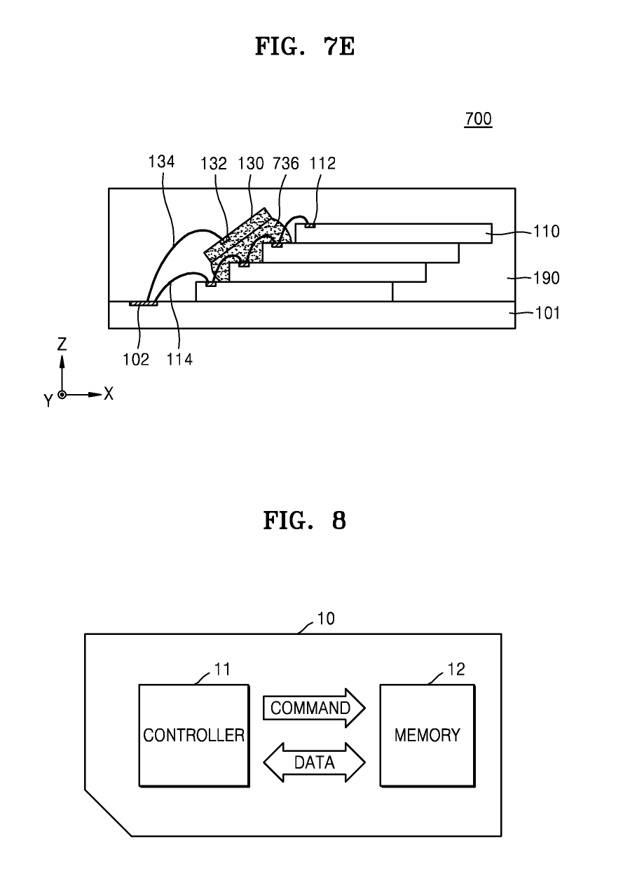

FIG. 9 is a schematic block diagram of an electric system 80 including a stack package according to exemplary embodiments. The electronic system 80 may be used in portable notebooks, MP3 players, navigation devices, SSDs, cars, or household appliances.

Referring to FIG. 9, an electronic system 80 may include a controller 81, an input/ouput apparatus 82, a memory 83 and an interface 84. The electronic system 80 may be a system that transmits or receives information including mobile systems. Examples of such mobile systems include personal digital assistants (PDA), portable computers, web tablets, wireless phones, mobile phones, digital music players and memory cards.

The controller 81 may perform a program and control the electronic system 80. The controller 81 may be a microprocessor, a digital signal processor, a microcontroller, or the like. The input/ouput apparatus 82 may be used to input or output the data of the electronic system 80.

The electronic system 80 may be connected to an external apparatus such as a personal computer or a network through the input/ouput apparatus 82 to exchange data with the external apparatus. The input/ouput apparatus 82 may be a keypad, a keyboard or a display. The memory 83 may store codes and/or data to operate the controller 81, or store the data processed in the controller 81. The controller 81 and the memory 83 may include a stack package according to an exemplary embodiment. The interface 84 may provide a path along which data can be transmitted between the electronic system 80 and an external apparatus. The controller 81, the input/output apparatus 82, the memory 83 and the interface 84 may communicate with each other through a bus 85.

Examples of applications of the electronic system 80 include those of a mobile phone, an MP3 player, a navigation, a portable multimedia player (PMP), a solid state disk (SSD) and household appliances.

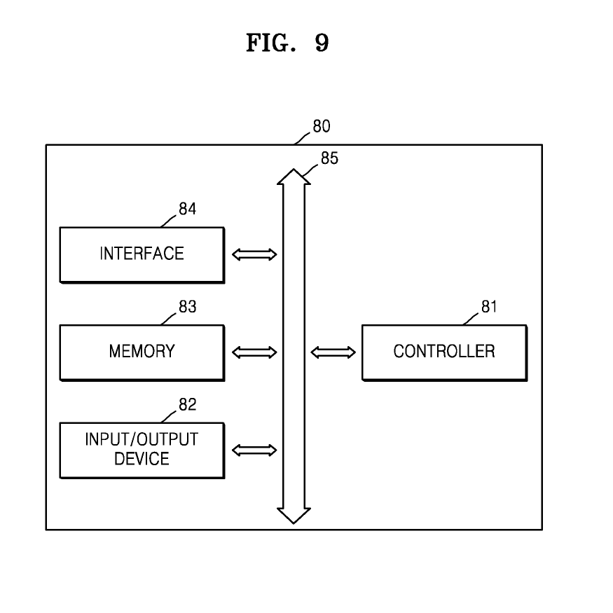

FIG. 10 schematically shows a solid state drive (SSD) employing a stack package according to exemplary embodiments of the present invention, which shows an example of a SSD apparatus employing the electric system of FIG. 9.

Referring to FIG. 10, SSD 30 may include a memory package 31, an SSD controller 33, a dynamic random access memory 35 (DRAM) and a main board 37.

The memory package 31, the SSD controller 33, and the DRAM 35 may include a stack package according to exemplary embodiments of the inventive concepts. However, the inventive concept is not limited thereto. In another example of this embodiment, the SSD includes a stack package that uses an internal seal and an external seal with different moduli.

The memory package 31 may be mounted on the main board 37 via a connecting member, and may include 4 memory packages PKG1, PKG2, PKG3, and PKG4. However, the inventive concept is not limited thereto, and more than four memory packages 31 may be provided depending on how many channels the SSD controller 33 supports. On the other hand, in cases in which a memory package 31 is formed of multiple channels, fewer than four (4) memory packages 31 may be provided.

The memory packages 31 may be mounted to the main board 37 via an external connecting member such as an array of solder balls, i.e., in the manner of a ball grid array (BGA) package. However, the memory packages 31 may be mounted in other manners. For example, the memory packages 31 may be mounted in the manner of a pin grid array (PGA), tape carrier package (TCP), chip-on board (COB), quad flat non-leaded (QFN), or quad flat package (QFP).

The SSD controller 33 may include eight (8) channels. The eight (8) channels may be connected to corresponding channels of the four (4) memory packages PKG1, PKG2, PKG3, and PKG4 in a one-to-one correspondence to control the semiconductor chips of the memory packages 31.

The SSD controller 33 may include a program that allows signal communication with an external device in a method based on a serial advanced technology attachment (SATA) standard, a parallel advanced technology attachment (PATA) standard, or a small computer system interface (SCSI) standard. Examples of the SATA standard include not only the so-called SATA-1 standard but also all SATA-based standards, e.g., SATA-2, SATA-3, and external SATA (e-SATA). Examples of the PATA standard include all integrated drive electronics (IDE)-based standards such as IDE and enhanced-IDE (E-IDE).

The SSD controller 33 may perform EEC, FTL, or the like. The SSD controller 33 may also embodied in package form and mounted to the main board 37. The SSD controller 33 may be mounted to the main board 37 in the manner of a BGA, PGA, TCP, COB manner, QFN, or QFP, like each memory package 31.

The DRAM 35 is an auxiliary memory device, and may serve as a buffer during data exchange between the SSD controller 33 and the memory package 31. The DRAM 35 may also be mounted to the main board 37 in any of various manners, e.g., in the manner of a BGA, PGA, TCP, COB, QFN, or (JP manner.

The main board 37 may be a PCB, a flexible PCB, an organic substrate, a ceramic substrate, a tape substrate, or the like. The main board 37 may include a core board (not shown) having an upper surface and a lower surface, and a resin layer (not shown) formed on each of the upper surface and the lower surface. The resin layers may be formed in a multi-layered structure, and a signal layer, a ground layer, or a power layer that forms a wiring pattern may be interposed between adjacent layers of the multi-layered structure. An additional wiring pattern may be formed on each resin layer. In FIG. 10, fine patterns shown on the main board 37 each illustrate a wiring pattern or a plurality of passive elements. An interface 39 for communication with an external device may be formed on one side, for example, the left side, of the main board 37.

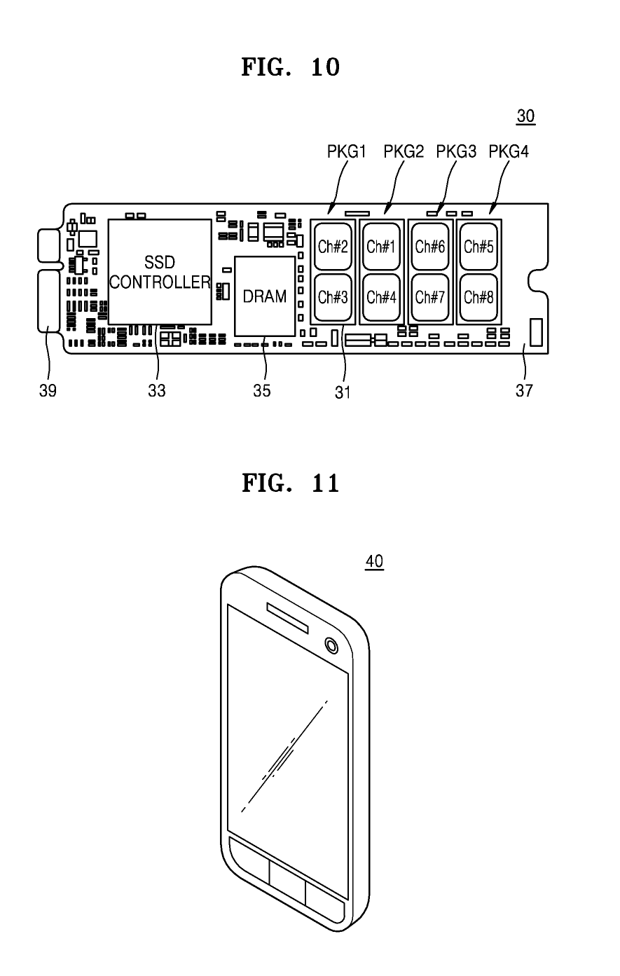

FIG. 11 is a schematic perspective view of an electronic apparatus employing a stack package according to exemplary embodiments. Specifically, FIG. 11 illustrates a mobile phone 40 as an example of an electronic apparatus to which the inventive concept may be applied. In this respect, the mobile phone 40 may employ the electronic system 80 of FIG. 9.

While the inventive concept has been particularly shown and described with reference to exemplary embodiments thereof, it will be understood that various changes in form and details may be made therein without departing from the true spirit and scope of the inventive concept as set forth in the following claims.

What is claimed is:

1. A semiconductor device package comprising:
a substrate;
a stack of semiconductor chips disposed on and mounted to the substrate, wherein the stack has a bottom at which the stack sits on the substrate, a top, and a side region extending between the bottom and the top of the stack;
at least one side semiconductor chip each attached to the stack of semiconductor chips at the side region of the stack of semiconductor chips; and
an adhesive member interposed between a lower surface of the at least one side semiconductor chip and the side region of the stack of semiconductor chips and by which the side semiconductor chip is attached to the stack of semiconductor chips.

2. The package of claim 1, wherein the at least one side semiconductor chip is inclined with respect to the substrate.

3. The package of claim 1, wherein the semiconductor chips of the stack are disposed stepwise in the stack, and
the side semiconductor chip is inclined with respect to the stack of semiconductor chips.

4. The package of claim 1, wherein the stack of semiconductor chips include a first semiconductor chip that is the lowermost one of the semiconductor chips in the stack semiconductor chips, a second semiconductor chip that is the uppermost one of the semiconductor chips in the stack, and a middle semiconductor chip interposed between the first semiconductor chip and the second semiconductor chip, and
wherein the at least one side semiconductor chip overlaps the middle semiconductor chip in a plan view of the package.

5. The package of claim 1, further comprising
a first connecting member that electrically connects the stack semiconductor chips and the substrate, and
a second connecting member that electrically connects the at least one side semiconductor chip and the substrate,
wherein at least some portions of the first connecting member are embedded in the adhesive member.

6. A semiconductor device package comprising:
a substrate including an insulating body having a plurality of sides, and connection pads disposed along at least one of the sides of the insulating body;
a stack of semiconductor chips disposed stepwise on the substrate, the semiconductor chips having a plurality of stack-chip connection pads exposed at a side of the stack;
at least one side semiconductor chip that has a plurality of side-chip connection pads at an upper surface thereof; and
an adhesive member attached to the stack at the side thereof where the stack-chip connection pads are exposed and by which the side semiconductor chip is attached to the stack.

7. The package of claim 6, further comprising a first connecting member connecting at least one said stack-chip connection pad of one of the semiconductor chips of the stack to at least one said stack-chip connection pad of another of the semiconductor chips of the stack, and
wherein the adhesive member covers at least some portions of the first connecting member.

8. The package of claim 6, wherein the adhesive member is spaced from the upper surface of the substrate.

9. The package of claim 6, wherein the adhesive member is an adhesive film having a film over wire (FOW) property.

10. The package of claim 6, wherein the adhesive member is spaced from the uppermost one of the semiconductor chips of the stack.

11. The package of claim 6, wherein at least one of the semiconductor chips of the stack is a memory chip, and
the at least one side semiconductor chip comprises a logic device.

12. The package of claim 6, wherein the at least one side semiconductor chip has a first side edge region along which the side-chip connection pads are disposed, and a second side edge region opposite the first side edge region, and
the first side edge region of the at least one side semiconductor chip is disposed at a level in the package lower than that at which the second side edge region is disposed.

13. The package of claim 6, wherein each said at least one side semiconductor chip is smaller than each of the semiconductor chips of the stack.

14. The package of claim 6, further comprising
a first connecting member that electrically connects at least one of the connection pads of the substrate and at least one of the stack-chip connection pads, and
a second connecting member that electrically connects at least one of the connection pads of the substrate and at least one of the side-chip connection pads.

15. The package of claim 14, wherein at least one of the first connecting member and the second connecting member comprises a bonding wire.

16. A semiconductor device package comprising:
an electronic substrate including a board having opposite major surfaces, and electrical connections including conductive pads disposed on one of the major surfaces;
a stack of first semiconductor chips mounted to the substrate on said one of the major surfaces,
wherein the stack has a bottom facing towards the substrate, a top facing away from the substrate, and side regions extending between the top and bottom, and
each of the first semiconductor chips is electrically connected to the electrical connections of the substrate;
a second semiconductor chip including a chip body having top and bottom surfaces, and conductive pads disposed along one of the surfaces of the chip body,
the second semiconductor chip being attached to the stack of semiconductor chips at one of the side regions of the stack of first semiconductor chips with said one of the surfaces of the chip body facing away from said one of the side regions of the stack and the other surface of the chip body facing towards said one of the side regions; and
electrical connectors electrically connecting the conductive pads of the second semiconductor chip to respective ones of the conductive pads of the electronic substrate.

17. The package as claimed in claim 16, wherein adhesive is interposed between the bottom surface of the chip body of the second semiconductor chip and said one of the side regions of the stack of first semiconductor chips and by which the second semiconductor chip is attached to the stack of first semiconductor chips.

18. The package as claimed in claim 16, wherein the electrical connectors are bonding wires.

19. The package of claim 18, wherein the first semiconductor chips include a lower first semiconductor chip, an upper first semiconductor chip, and at least one middle first semiconductor chip interposed between the lower and upper semiconductor chips in the stack,
each of the first semiconductor chips includes a first chip body having top and bottom surfaces, and conductive pads disposed alongside the periphery of one of the surfaces of the first chip body,
the first semiconductor chips are horizontally offset from one another in the stack such that the conductive pads of each the first semiconductor chips are disposed on the outside of the stack with the conductive pads of each said at least one middle first semiconductor chip being disposed at one of the side regions of the stack,
the top and bottom surfaces of the second semiconductor chip extend obliquely relative to the top and bottom surfaces of the first semiconductor chips, and
bonding wires electrically connect the conductive pads of the first semiconductor chips to respective ones of the conductive pads of the electronic substrate.

20. The package of claim 19, wherein a body of adhesive is interposed between the bottom surface of the chip body of the second semiconductor chip and said one of the side regions of the stack of first semiconductor chips and by which the second semiconductor chip is attached to the stack of first semiconductor chips, and
respective ones of the bonding wires that electrically connect the conductive pads of the first chips to respective ones of the conductive pads of the electronic substrate are embedded in the adhesive.
